(19) United States
(12) Patent Application Publication
(10) Pub. No.: US 2026/0205727 A1
(43) Pub. Date: Jul. 16, 2026

(54) Display with Integrated Speaker

(71) Applicant: Sky CP Limited, Isleworth, Middlesex (GB)

(72) Inventors: Andrew Aristidou, Isleworth, Middlesex (GB); Gregory Cruse, Isleworth, Middlesex (GB)

(73) Assignee: Sky CP Limited, Isleworth, Middlesex (GB)

(21) Appl. No.: 18/870,914

(22) PCT Filed: Dec. 23, 2022
(86) PCT No.: PCT/GB2022/053384

§ 371 Date: Dec. 2, 2024

(30) Foreign Application Priority Data
Jun. 1, 2021 (GB) 2208127.7

(51) Int. Cl. H04R 1/02; H05K 5/02

(52) U.S. Cl. CPC H04R 1/028; H04R 1/025; H05K 5/0217; H04R 2499/15

(57) ABSTRACT

A display such as a TV, monitor or other type of display includes a display screen, a back cover, and at least one integrated speaker. A bracket or non-planar sheet of rigid material is disposed between the screen and the back cover so as to define an internal cavity coupled to the at least one speaker. The cavity may insulate the screen and/or electronic components between the screen and the back cover from audio vibrations, which may reduce or avoid defects or distortion in the screen, damage to the electronic components and/or audible distortion such as buzzing. The cavity may also enhance the audio quality of the speaker.

### FIELD OF THE INVENTION

The present invention relates to a display, such as but not limited to a flat screen TV, with at least one integrated speaker.

### BACKGROUND OF THE INVENTION

In displays such as TV sets or monitors with integrated speakers, the sound from the speakers may interfere with other components. The speakers are typically positioned close to or in contact with other components within the display, which may cause the components to vibrate and rattle. The vibrations can also cause visible distortion or defects (e.g. mura) in the display screen. Reducing these negative effects may require clearance between the speakers and the other components which may result in a thicker display and/or additional damping components which complicate assembly of the display. The speakers may be placed within an enclosure separate to the display. The speaker enclosure is generally mounted via vibration reducing dampers/grommets to the back cover of the display. The enclosure and grommets require respective clearances for them to be mounted within the display, increasing the depth of the overall display.

The audio quality of integrated speakers may be affected by the housing in which they are mounted, particularly for low-frequency speakers which are affected by the volume and shape of the housing. However, optimizing the audio quality may require a larger or inconveniently shaped housing.

### STATEMENT OF THE INVENTION

Aspects of the invention are defined by the accompanying claims.

In an embodiment of the invention, display apparatus such as a TV, monitor or other type of display includes a display screen, a back cover for the display screen, and at least one integrated speaker. A bracket, baffle or partition is disposed between the screen and the back cover so as to define an internal cavity coupled to the at least one speaker. The back cover may form a back wall of the cavity and the speaker(s) may be mounted in a corresponding aperture or apertures in the back cover. The cavity may insulate the screen and/or electronic components between the display screen and the back cover from audio vibrations, which may reduce or avoid defects or distortion in the screen, damage to the electronic components and/or audible distortion such as buzzing. The cavity may also enhance the audio quality of the speaker.

The bracket may comprise a non-planar sheet of rigid material, and may include a ridge or projection that defines a wall or walls (e.g. side walls) of the cavity. The ridge may be sealed against an internal surface of the back cover, for example by a gasket that is formed in place or pre-formed. This arrangement forms the cavity in a simple manner, using few additional components e.g. the bracket, the gasket (if used) and possibly a modification to the design of the back cover.

A portion of the back cover that forms a back wall of the cavity may protrude in a direction away from the screen, to increase the volume of the cavity. This protrusion may be shaped to optimize the sound quality of the speaker.

The speaker may be a low frequency range speaker and may be a rear and/or upward firing speaker.

### BRIEF DESCRIPTION OF THE DRAWINGS

There now follows, by way of example only, a detailed description of embodiments of the present invention, with reference to the figures identified below.

FIG. 1 is an isometric view of the back of a TV in an embodiment of the invention.

FIG. 2 is an exploded view of the TV.

FIG. 3 is a back view of the TV with the location of a cross-sectional view.

FIG. 4a is a side view of the TV.

FIG. 4b is a cross-sectional view in a vertical plane A-A of FIG. 4a.

FIG. 4c is a detailed view of the circled area of FIG. 4b.

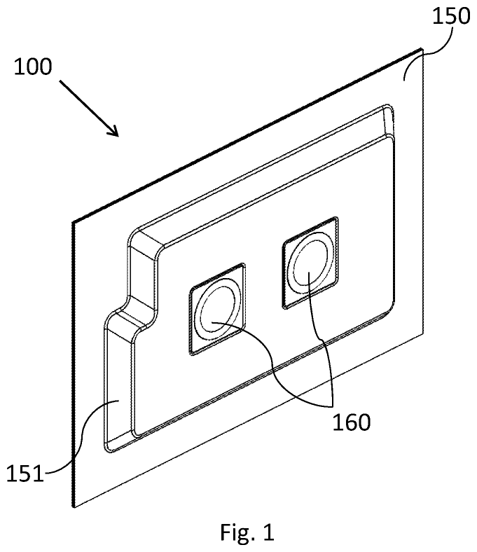

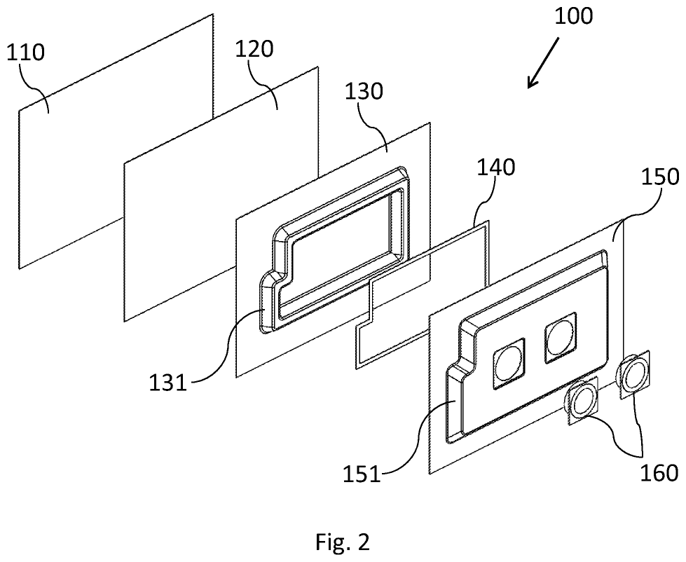

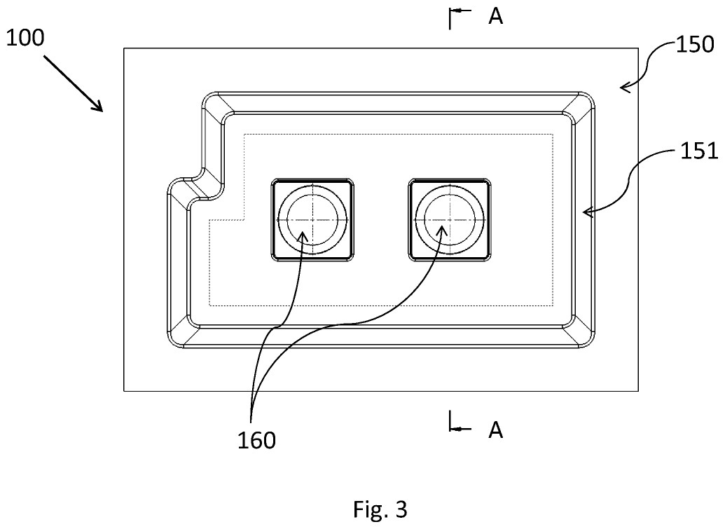

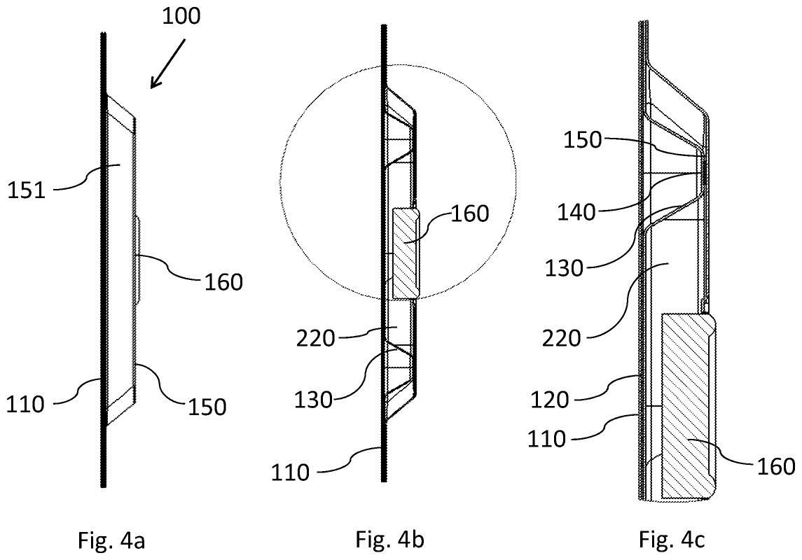

### DETAILED DESCRIPTION

A flat screen display, such as a TV 100, in an embodiment of the invention comprises a screen 110, back cover 150, and at least one speaker 160 each mounted in respective aperture in the back cover 150. In a finished product, there may be provided a housing e.g. a frame around the screen 110 and/or a rear housing mounted behind the back cover 150.

The speaker(s) 160 may comprise one or more rear-or upward-firing woofers, i.e. low frequency speakers with a frequency response range from 20-50 Hz to 200-2,000 Hz. Audio signals in this range are typically non-directional for typical sizes of speaker, so that low-frequency speakers may be positioned at the back of the display rather than directed towards the listener.

The screen 110 may be an OLED (organic light emitting diode) display, although other suitable screen technologies such as Mini LED are also applicable. Such displays may be susceptible to visible distortion or defects (e.g. mura) from audio frequency vibrations.

An inner plate 120, which may be made of steel, may be mounted behind the screen 110 for structural integrity and support. In alternative embodiments the inner plate 120 may be integrated with the screen 110 or may be omitted.

An intermediate plate or bracket 130 is located between the screen 110/inner plate 120 and the back cover 150 so as to form a cavity 220 between the bracket 130 and the back cover 150. The bracket 130 is non-planar and may have a ridge 131, positioned inwardly from the edges of the bracket 130, that extends towards the back cover 150 so as to define side walls of the cavity 220. The ridge 131 may be trapezoid in cross-section. The bracket 130 may be made of steel or other rigid material. The bracket 130 may be formed from a planar sheet of material that is shaped to form the ridge 131, for example by pressing.

The ridge 131 may be sealed against the inner surface of the back cover 150 by a gasket 140 or other type of seal; this may be formed in place by applying sealant to the protruding surfaces of the ridge 131, or the seal may be pre-formed and then applied to the protruding surfaces. The seal at least partially seals the interior of the cavity 220 from the internal space around the cavity 220 so as to reduce sound leakage into other internal parts of the TV 100.

The portion of the back cover 150 that forms a wall of the cavity 220 may be shaped to increase the volume of the cavity 220, for example by protruding away from the screen 110 as a protrusion 151.

The cavity 220 is coupled to the speaker(s) 160 such that audio vibrations from the rear of the speaker(s) 160 enter the cavity 220, which forms a closed volume within the space between the screen 110/inner plate 120 and the back cover 150. This may enhance the audio quality of the speakers 160.

The cavity 220 may additionally serve as a sound insulator between the speaker(s) 160 and the screen 110 and/or other internal components of the TV 100. This may prevent or reduce buzzing or rattling of internal components, which may not only protect the components from long-term damage, but also removes or reduce the need for internal damping components, such as rubber grommets separating each component within the TV 100.

The cavity 220 may also act as an amplifier for the speakers 160 by providing a sound box effect, thereby increasing the speakers'160 effective output volume.

In addition, clearance between the speaker(s) 160 and the screen 110 and/or other internal components within a TV 100 may be reduced, or at least the space occupied by the cavity 220 may provide one or more of the advantages discussed above rather than being dead space, or space that is not optimized for the speaker(s) 160.

The ridge 131 and/or protrusion 151 allow flexibility of design, since their shape and/or size is not significantly constrained by other components, so that the shape and/or size of the cavity 220 may be designed so as to optimize one or more of the effects described above.

Variants of the above embodiments, which may occur to the skilled person on reading the above description, may nevertheless fall within the scope of the invention as defined by the following claims.

1. Display apparatus, comprising:
a display screen having a back cover,
at least one integrated speaker mounted in a respective aperture in a portion of the back cover; and
a bracket arranged in a space between the screen and the back cover, the bracket and the portion of the back cover together defining an internal cavity within the space between the display screen and the back cover, such that the internal cavity is coupled to the at least one speaker.

2. Apparatus of claim 1, wherein the bracket includes a ridge that defines a wall of the cavity.

3. Apparatus of claim 2, wherein the ridge is sealed against an internal surface of the back cover.

4. Apparatus of claim 2, wherein the bracket comprises a sheet of rigid material that is shaped to form the ridge.

5. Apparatus of claim 1, wherein an inner plate is mounted between the display screen and the bracket.

6. Apparatus of claim 1, wherein the portion of the back cover that forms a wall of the cavity protrudes in a direction away from the display screen.

7. Apparatus of claim 1, wherein the at least one speaker comprises at least one low frequency speaker.

8. Apparatus of claim 1, where the at least one speaker comprises at least one rear and/or upward firing speaker.

9. Apparatus of claim 1, wherein the display screen is an OLED display screen.

10. Apparatus of claim 2, wherein the ridge is positioned inwardly from the edges of the bracket.
